(19) United States
(12) Patent Application Publication
(10) Pub. No.: US 2002/0053695 A1
(43) Pub. Date: May 9, 2002

(54) Split buried layer for high voltage LDMOS transistor

(76) Inventors: Chorng-Wei Liaw, Huwei Jen (TW); Chin-Horng Chang, Tainan City (TW); Wei-Jye Lin, Chaujou Jen (TW); Ming-Jang Lin, Taiping Shiang (TW); Tian-Fure Shiue, Judung Jen (TW); Huang-Chung Cheng, Hsinchu (TW); Ching-Hsiang Hsu, Hsinchu (TW)

Correspondence Address: RABIN & CHAMPAGNE, P.C., Suite 500, 1101 14th Street, N.W., Washington, DC, 20005, US

(21) Appl. No.: 09/916,337

(22) Filed: Jul. 30, 2001

(30) Foreign Application Priority Data
Nov. 7, 2000 (TW) 089123530

(51) Int. Cl. H01L 29/94

(52) U.S. Cl. 257/328

(57) ABSTRACT

A split buried layer for high voltage lateral double-diffused metal-oxide-semiconductor (LDMOS) transistor formed on a semiconductor substrate is disclosed to increase the breakdown voltage of the LDMOS. The LDMOS comprises a drain, a source, a gate channel between the drain and source, a gate to control the gate channel, a drift region between the drain and gate channel, and the buried layer between the drift region and the substrate. The improvement is that at least one field trap is formed in the buried layer under the drift region. A method of forming the split buried layer comprises formation of a lightly doped region or a doping discontinuity at a position corresponding to the field trap, and then driving the dopant to form a doping concentration profile laterally-split at the field trap. In other embodiment methods, the split buried layer is formed by a recess in thickness, or a lighter or deeper profile in concentration at the field trap.

### FIELD OF THE INVENTION

The present invention relates generally to a high voltage lateral double-diffused metal-oxide-semiconductor (LDMOS) transistor, and more particularly, to a split buried layer for high voltage LDMOS transistor.

### BACKGROUND OF THE INVENTION

Due to its low power consumption, the LDMOS transistor with low on-resistance and high breakdown voltage is desired for high voltage applications. Such device can be known from U.S. Pat. No. 5,517,046 for example. The breakdown voltage and on-resistance are two important factors for the performance of an LDMOS transistor. FIG. 1 illustrates the structure of a typical P type LDMOS transistor 100. A heavily doped N type buried layer 12, a P-well 14, and an N-well 16 are formed on a P type substrate 10, a heavily doped P-region 18 is formed on the surface of the P-well 14 and used as a drain region, a heavily doped P-region 20 is formed on the surface of the N-well 16 and used as a source region, a heavily doped N-region 22 is formed on the surface of N-well 16 and used as a ground region, and it is electrically connected with the source region 20; a dielectric layer 24, e.g., silicon dioxide, is formed between the drain region 18 and the source region 20, it is extended to the edge of the source region 20 from the edge of the drain region 18, and a gate electrode layer 26 is also formed on the top of the dielectric layer 24, which is extended to the top of the P-well 14 from the edge of the source region 20; a gate channel region 28 formed on the surface of the N-well 16 is under the gate electrode layer 26 and the dielectric layer 24, and under the dielectric layer 24 and between the drain region 18 and the interface of the P-well 14 and N-well 16 is a drift region. In the LDMOS transistor 100, the N⁺ buried layer 12 is used for electric isolation of the high-voltage component and the P type substrate 10; however, although the buried layer 12 can effectively protect the low-voltage component from high-voltage damages, it also imposes restrictions on the withstanding of the high-voltage component. In particular, the positions can be happened with breakdown for traditional LDMOS transistors are indicated with A, B, C, and D as shown in FIG. 1. Region A is the position corresponding to the P-N surface breakdown, region B is the position corresponding to the field plate edge breakdown, region C is the position corresponding to the P-i-N reach-through breakdown, and region D is the position corresponding to the P-N planer breakdown. When a breakdown occurs in region D, it means that the breakdown limit has been reached and that there is no way to improve the breakdown voltage unless the doping concentration in the P-well 14 is made lighter or the junction becomes deeper (i.e., the epitaxial layer becomes thicker).

However, there usually exists a tradeoff between the breakdown voltage and the on-resistance in a high-voltage LDMOS transistor, which is meant to increase the breakdown voltage and at the same time the on-resistance is kept on a relatively low level. The on-resistance will become larger if the doping concentration is decreased in order to increase the breakdown voltage, while it cannot be improved with the breakdown voltage if low on-resistance is retained. Therefore, an improvement is desired on the high-voltage LDMOS transistor for simultaneously obtaining high breakdown voltage and low on-resistance.

### SUMMARY OF THE INVENTION

The object of the present invention is to provide an improved high-voltage LDMOS transistor, in which a split buried layer is formed between the drift region and the semiconductor substrate of the LDMOS transistor as a field tap so that the density of the electric field under the drift region is made uncrowded and the surface voltage withstanding of the buried layer can be improved. By the same manufacture process and with the same on-resistance, the split buried layer can significantly increase the breakdown voltage of the LDMOS transistor.

According to the present invention, a high-voltage LDMOS transistor with improved buried layer comprises a semiconductor substrate above which a first semiconductor region of a first conductivity type and a second semiconductor region of a second conductivity type opposite to the first conductivity type are formed and a first and a second electrode regions of the first conductivity type are formed on the surface of the first and second semiconductor regions respectively, a gate dielectric layer formed between the first and second electrodes, a gate electrode layer above the gate dielectric layer, and a buried layer of the second conductivity type between the substrate and the first semiconductor region is formed with a portion of the buried layer under the first semiconductor region as at least one field trap.

The improved buried layer structure is formed with a recess in thickness or in doping concentration profile of the buried layer to obtain the field trap so that the field trap is deeper than its neighborhood in view of the surface of the first semiconductor region. Alternately, the doping concentration of the field trap is made less than that of its neighborhood.

The way to form the improved buried layer is that the position corresponding to the field trap is preformed with a lighter doping region or a doping discontinuity by a doping process, and then the dopant in the lighter doping region or the doping discontinuity is driven to form a profile which is a laterally-split buried layer centered at the field trap. Alternately, the buried layer is formed with a recess in thickness at the field trap, or the buried layer is made to have lighter doping concentration or made deeper at the field trap.

### BRIEF DESCRIPTION OF THE DRAWINGS

For a better understanding of the present invention, reference may be had to the following description of exemplary embodiments thereof, considered in conjunction with the accompanying drawings, in which:

FIG. 1 illustrates the structure of a typical P type LDMOS transistor;

FIG. 2 illustrates an embodiment of the structure for a P type LDMOS transistor according to the present invention;

FIG. 3 illustrates the simulation of the equi-potential level distribution for the conventional transistor shown in FIG. 1;

FIG. 4 illustrates the simulation of the equi-potential level distribution for the improved transistor shown in FIG. 2;

FIG. 5 illustrates the comparison between the simulations of the breakdown voltage for the embodiment of the present invention and the prior art transistor;

FIG. 6 illustrates the comparison between the simulations of the drain current-voltage curves for the embodiment of the present invention and the prior art transistor;

FIG. 7 illustrates the comparison between the experiment results of the breakdown voltage curve for the embodiment of the present invention and the prior art transistor;

FIG. 8 illustrates the comparison between the simulations of the I-V curve for the embodiment of the present invention and the prior art transistor;

FIG. 9 illustrates the first embodiment of the split buried layer according to the present invention;

FIG. 10 illustrates the second embodiment of the improved buried layer according to the present invention;

FIG. 11 illustrates the third embodiment of the buried layer for the LDMOS transistor according to the present invention; and

FIG. 12 illustrates the structure for a P-type LDMOS transistor of a further embodiment according to the present invention.

### DETAILED DESCRIPTION OF THE INVENTION

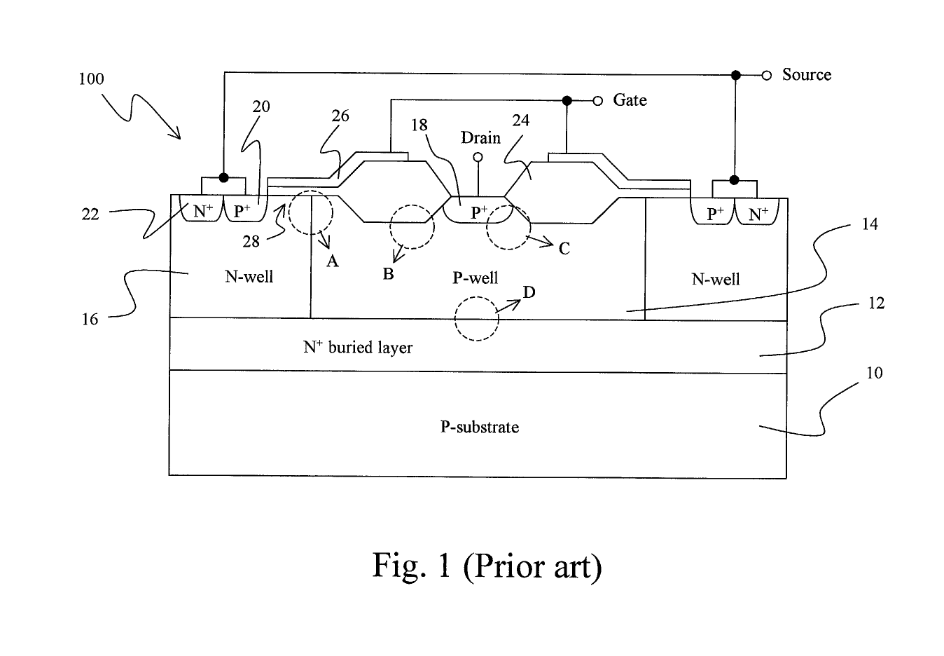

The following description for the present invention employs a P-type LDMOS transistor as embodiments but not limitations, thus other types of LDMOS transistor are also available. Those who are skilled in the art should know that the present invention can also apply to various types of LDMOS transistor. Moreover, for better explanation and illustration of the features and advantages of the present invention, the embodiments provided are designed based on the well-known P type LDMOS transistor shown in FIG. 1 and thus the comparison with the transistor shown in FIG. 1 is provided. However, the present invention is not limited to such type of transistors. Those who are skilled in the art should know that the present invention can also apply to other or modified LDMOS transistors, without departure from the scope of the present invention.

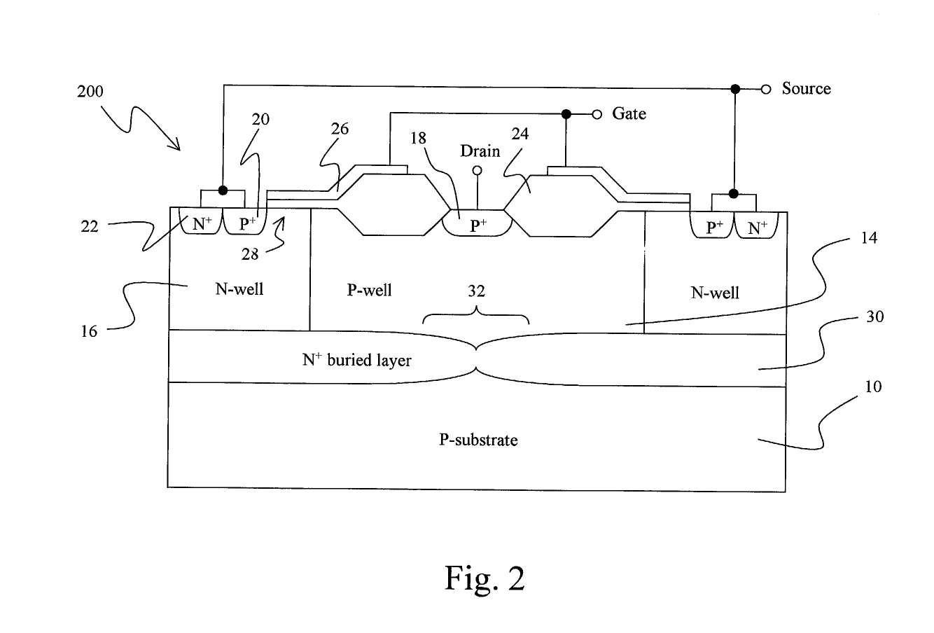

FIG. 2 illustrates an embodiment of a P type LDMOS transistor according to the present invention. The basic structure and principle of the device 200 are same as those of the typical P type LDMOS transistor shown in FIG. 1 only that a buried layer 30 thereof has a split structure which is split from below the drain region 18 and thus a field trap 32 is formed. When viewing from the bottom of the drain region 18, the field trap 32 is deeper than its neighborhood in the buried layer 30 so that the field trap 32 is farther from the bottom of the drain region 18. That is, the P-well 14 between the field trap 32 and the drain 18 is thicker so as to change the electric field distribution.

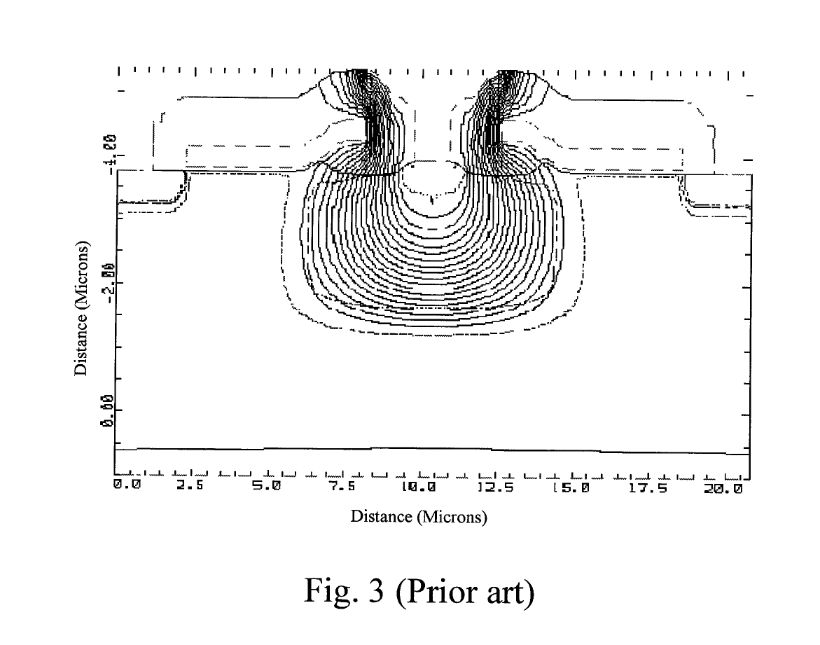

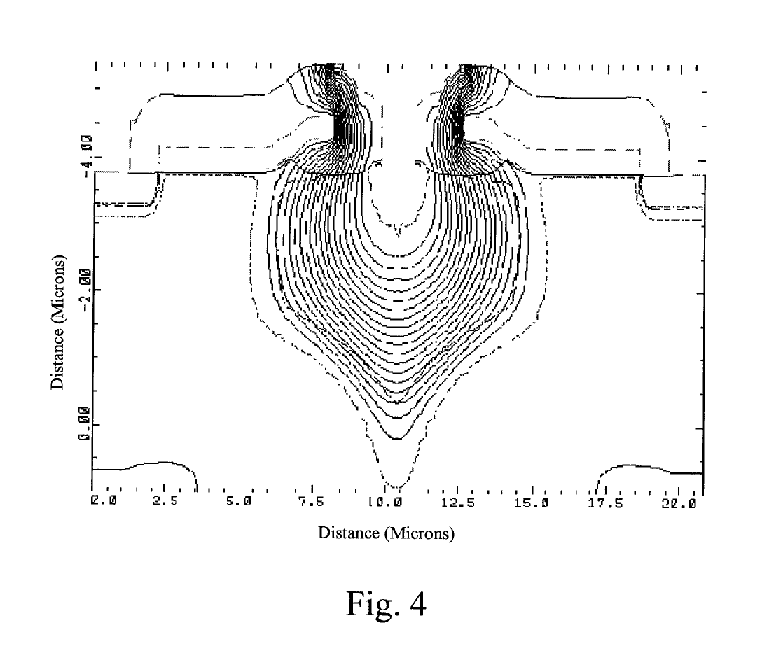

To illustrate the electric field distribution resulted from the split buried layer 30 of the present invention, there provides the simulations of the equi-potential level distribution for the transistors 100 and 200 shown in FIGS. 1 and 2 respectively. In FIG. 3 it is illustrated the simulation of the equi-potential level distribution for the transistor 100 shown in FIG. 1, and in FIG. 4 it is illustrated the simulation of the equi-potential level distribution for the transistor 200 shown in FIG. 2. As shown in FIG. 3, the bottom of the potential level has flatter equi-potential surface due to the flat and uniform surface of the buried layer 12 shown in FIG. 1. In this manner, the equi-potential surface of the P-well 14 near the interface of the buried layer 12 becomes crowded, and therefore there is higher density of electric field. While, as shown in FIG. 4, the bottom of the potential level distribution of the P-well 14 in FIG. 2 stretches downward due to the presence of the field trap 32 where the equi-potential surface is made uncrowded and there is less density of electric field. Therefore, the surface voltage withstanding of the split buried layer 30 is increased.

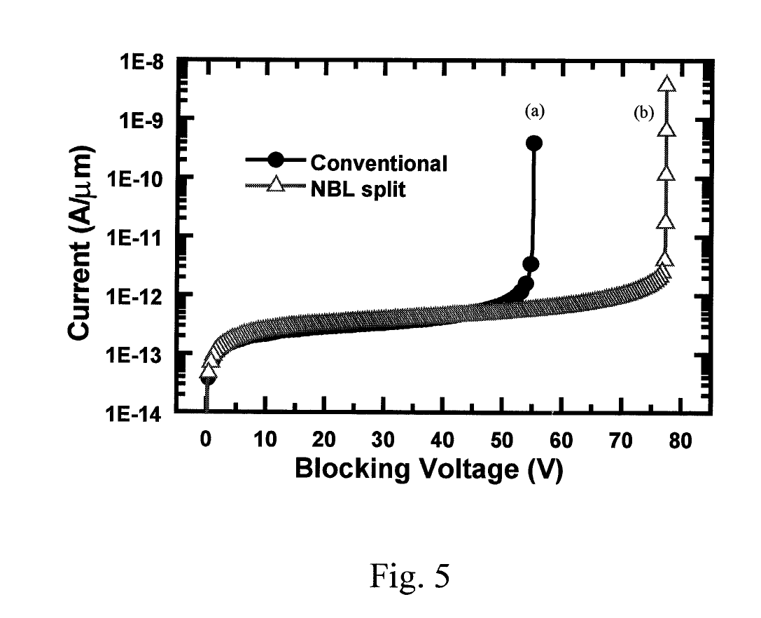

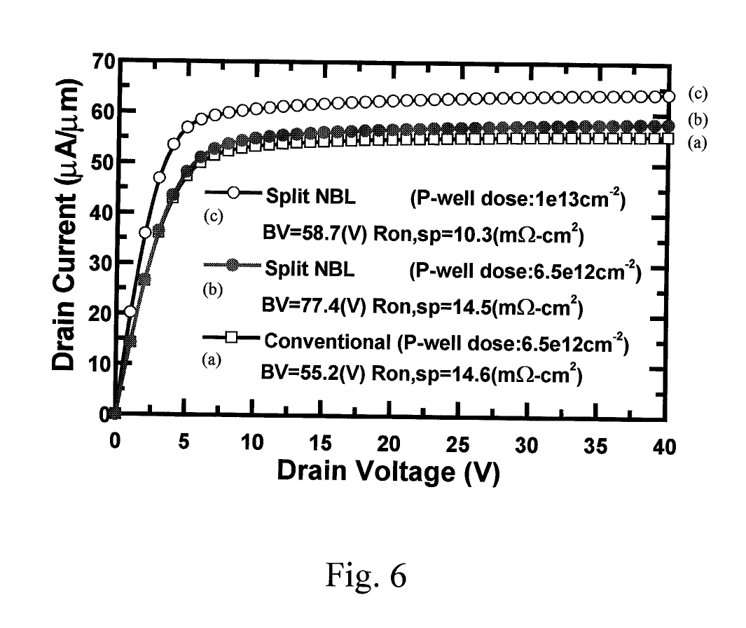

FIG. 5 illustrates the comparison of the simulations for the embodiment transistor 200 of the present invention and the prior art transistor 100 on their breakdown voltages under same manufacture process. The curve (a) shows the characteristics of the transistor 100 whose breakdown voltage is about 55 volts; while the curve (b) shows the characteristics of the transistor 200 whose breakdown voltage is about 77 volts, which is about 40% more than that of the transistor 100. FIG. 6 illustrates the comparison of the simulations for the embodiment transistor 200 of the present invention and the prior art transistor 100 on their drain current-voltage curves. The curve (a) shows the characteristics of the transistor 100 whose breakdown voltage is 55.2 volts and whose on-resistance is 14.6 mΩ−cm², while for the P-well 14 with the same doping concentration of 6.5×10¹² cm⁻² in the embodiment of the present invention shown in curve (b), whose breakdown voltage is 77.9 volts and whose on-resistance is 14.5 mΩ−cm², which means that the breakdown voltage is increased by 40% for the same on-resistance. As shown in curve (c), for another embodiment which has the same structure as that of the embodiment transistor of the curve (b) while the doping concentration in the P-well 14 increased to 1×10¹³ cm⁻², the breakdown voltage is 58.7 volts and the on-resistance is 10.3 mΩ−cm². In other words, its breakdown voltage is a little more than that of the transistor 100 (about 6.34%) but its on-resistance is significantly decreased (about 29.45%). As in the description, the present invention can increase the breakdown voltage and decrease the on-resistance only by improving the structure of the buried layer of the LDMOS transistor, without further complicating the manufacture process.

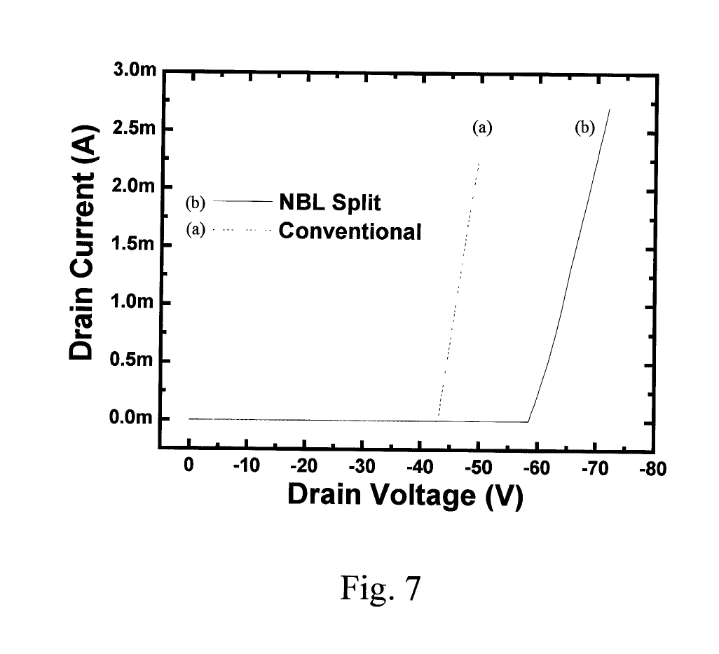

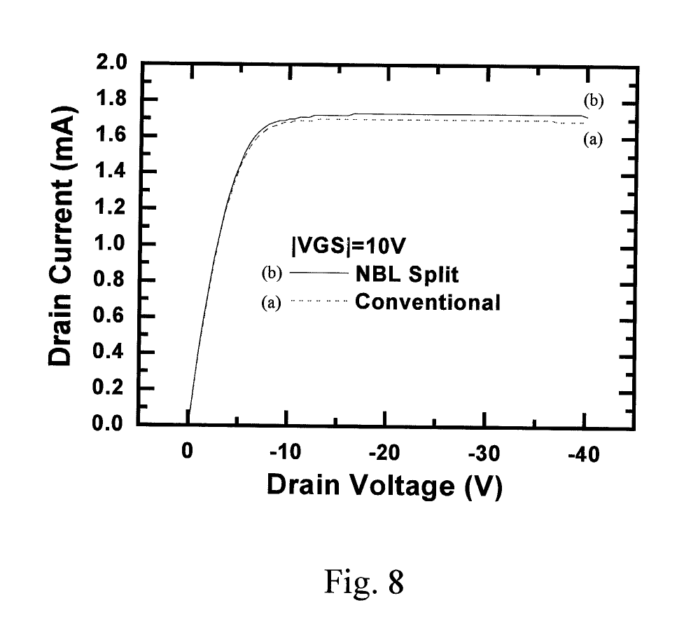

To justify the present invention, experiments on the breakdown voltage curve and I-V curve for the present invention and the prior art transistor are done and the results are shown in FIGS. 7 and 8 respectively. In FIG. 7, curve (a) is the breakdown curve for the prior art transistor and curve (b) is that for the present invention. As shown in the figure, the breakdown voltage of the present invention is about 15 volts higher than that of the prior art transistor. In FIG. 8, curve (a) is the I-V curve for the prior art transistor and curve (b) is that for the present invention. As shown in the figure, the characteristics for both of them are similar. It is known from FIGS. 7 and 8 that the present invention can significantly increase the breakdown voltage up to more than one third for a given I-V characteristics.

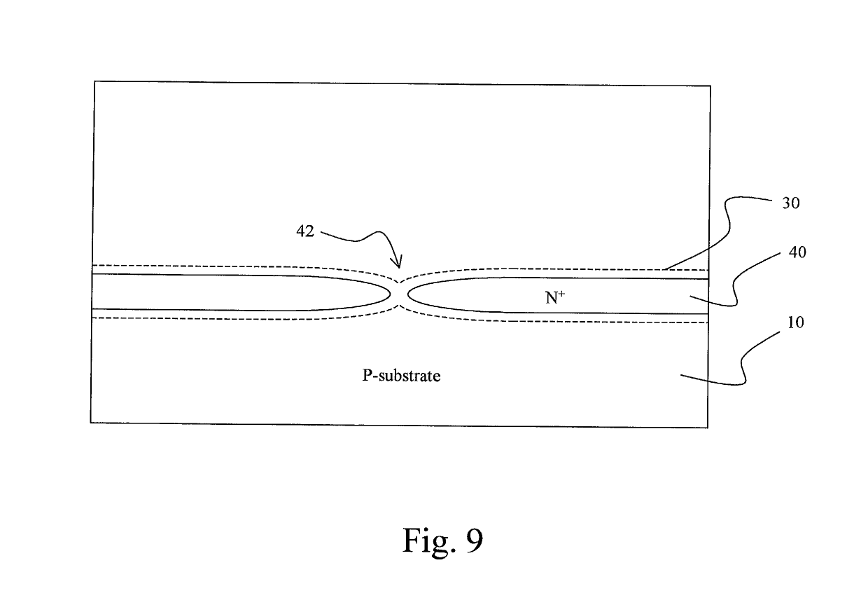

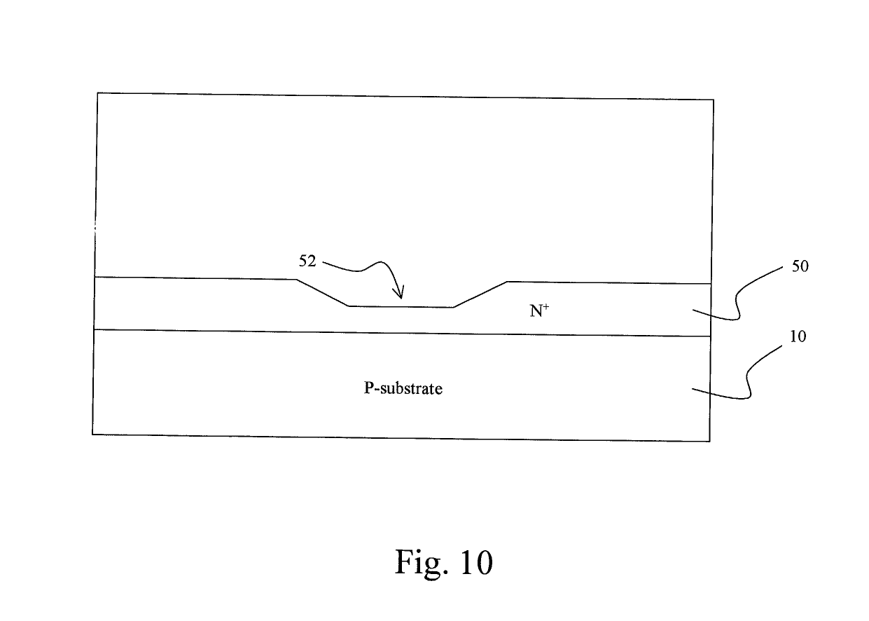

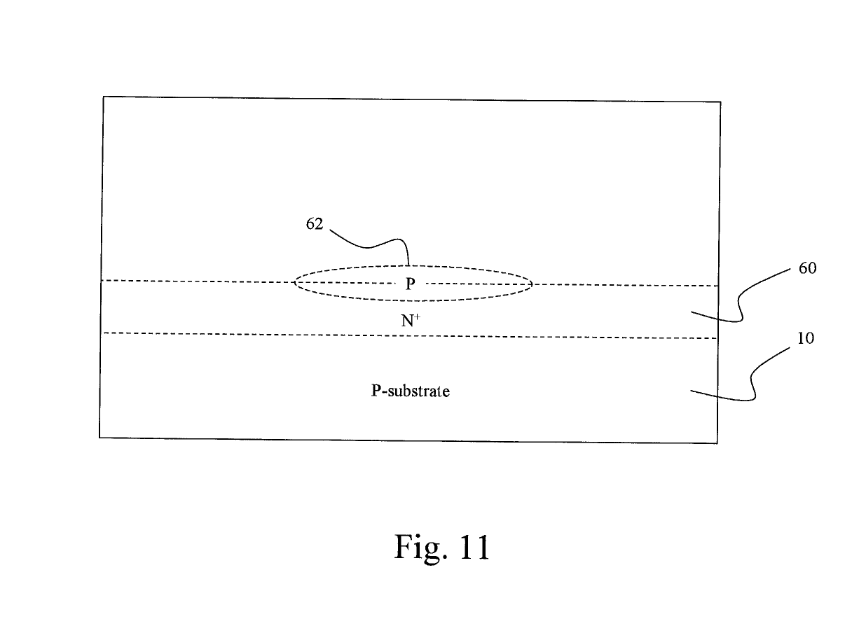

There are many different embodiment structures and methods of the present invention for the improved buried layer of the LDMOS transistor. As shown in FIG. 9, the ion implantation is applied to the P-substrate 10 to form an N type heavily doped region 40. As shown in the figure, the buried layer is pre-doped with a discontinuity 42, the surrounding doping concentration profile is narrower, and then a thermal treatment is employed to drive the N type heavily doped region 40 to diffuse so as to form the buried layer 30. The implementation that follows for other structure of the LDMOS transistor, including the drift region, source, drain and gate, are same as the prior art, so they are not further discussed hereto. Another embodiment for the buried layer according to the present invention is shown in FIG. 10. In this embodiment, an uneven N type heavily doped buried layer 50 is formed on the P-substrate 10, and the portion corresponding to the drain region is formed with a recess 52 so that its surface is deeper. A process, such as thermal diffusion, can be used to form a flat and even N type heavily doped region, and then the recess 52 can be selectively etched; alternately, a trench can be pre-etched on the substrate 10, and then a process, such as thermal diffusion, is used to proceed with the N type doping. Similarly, the prior art can be used in the manufacturing process that follows. FIG. 11 illustrates another embodiment for the buried layer according to the present invention, in which doping process is applied twice. At first, a process, such as thermal diffusion, is used on the P-substrate 10 to form an N type heavily doped region 60, and then a second process, such as ion implantation and thermal diffusion, is used to form a P type doping region 62 so that the N type dopant is compensated by the P type dopant and the N type doping concentration in that region 62 is made lighter. As a result, the doping concentration profile of the buried layer in that region 62 is in turn recessed.

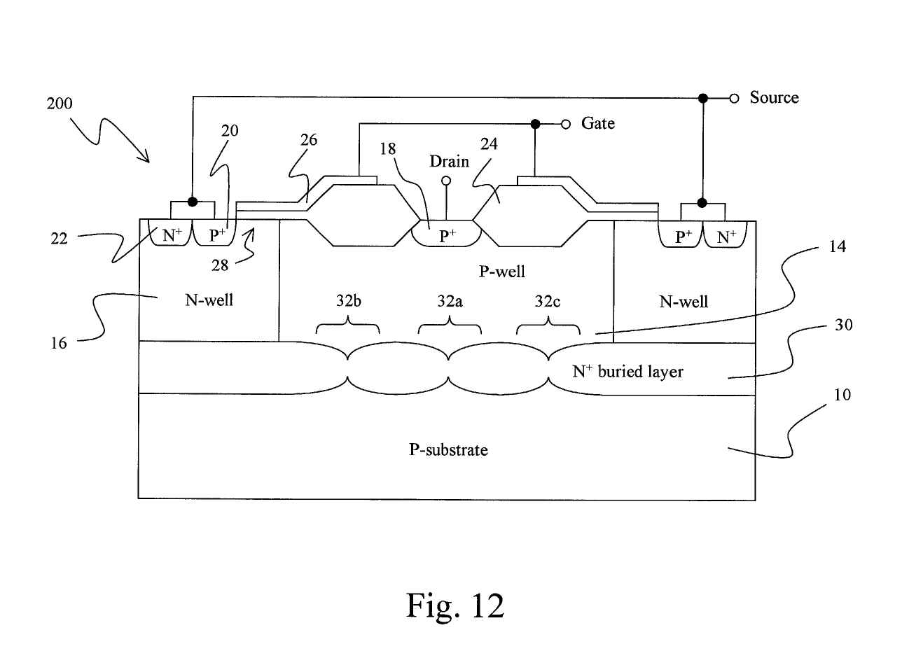

The above embodiments place the field trap directly under the drain region and there is only one field trap; however, from the principle of the invention, the field tap is not necessarily placed directly under the drain region, and there can be more than one field trap. FIG. 12 illustrates another embodiment with such reasoning. In this embodiment, the portion of the split buried layer 30 within the drift region 14 has three field traps 32a, 32b, and 32c. These field traps can make the density of electricity field in the drift region 14 uncrowded, so that the surface voltage withstanding of the buried layer 30 is increased.

From the above, it should be understood that the embodiments described, in regard to the drawings, are merely exemplary and that a person skilled in the art may make variations and modifications to the shown embodiments without departing from the spirit and scope of the present invention. All variations and modifications are intended to be included within the scope of the present invention as defined in the appended claims.

What is claimed is:

1. A high voltage lateral double-diffused metal-oxide-semiconductor transistor with an improved buried layer comprising:
a semiconductor substrate;
a first semiconductor region of a first conductivity type formed on said substrate;
a first electrode region of said first conductivity type formed on a surface of said first semiconductor region;
a second semiconductor region of a second conductivity type opposite to said first conductivity type formed on said substrate and adjoining to said first semiconductor region;
a second electrode region of said first conductivity type formed on a surface of said second semiconductor region;
a gate dielectric formed between said first and second electrode regions;
a gate electrode formed on said gate dielectric; and
a buried layer of said second conductivity type formed between said substrate and first semiconductor region with at least one field trap formed at a surface of said buried layer adjoining to said first semiconductor region.

2. A transistor of claim 1 wherein said field trap is formed with a recess in thickness of said buried layer.

3. A transistor of claim 1 wherein said field trap is formed with a recess in doping concentration profile of said buried layer.

4. A transistor of claim 1 wherein said field trap is deeper than its neighborhood of said buried layer in view of the surface of said first semiconductor region.

5. A transistor of claim 1 wherein said field trap has a thickness less than that of its neighborhood of said buried layer.

6. A transistor of claim 1 wherein said field trap has a doping concentration less than that of its neighborhood of said buried layer.

7. A transistor of claim 1 wherein said buried layer has a profile laterally split at said field trap.

8. In a high voltage lateral double-diffused metal-oxide-semiconductor transistor with a buried layer formed on a semiconductor substrate, said transistor having a drain, a source, a gate channel between said drain and source, a gate for control of said gate channel, and a drift region between said drain and gate channel, said buried layer formed between said drift region and substrate, an improvement comprising:
at least one field trap formed at a surface of said buried layer adjoining to said drift region.

9. An improvement of claim 8 wherein said field trap is formed with a recess in thickness of said buried layer.

10. An improvement of claim 8 wherein said field trap is formed with a recess in doping concentration profile of said buried layer.

11. An improvement of claim 8 wherein said field trap is deeper than its neighborhood of said buried layer in view of the surface of said first semiconductor region.

12. An improvement of claim 8 wherein said field trap has a thickness less than that of its neighborhood of said buried layer.

13. An improvement of claim 8 wherein said field trap has a doping concentration less than that of its neighborhood of said buried layer.

14. An improvement of claim 8 wherein said buried layer has a profile laterally split at said field trap.

15. A method of forming a buried layer for a high voltage lateral double-diffused metal-oxide-semiconductor transistor on a semiconductor substrate comprising the following steps of:
forming a non-uniform heavily doped region on said substrate; and
driving said heavily doped region to form a split structure.

16. A method of forming a buried layer for a high voltage lateral double-diffused metal-oxide-semiconductor transistor on a semiconductor substrate comprising the following steps of:
forming a trench on a surface of said substrate; and
heavily doping said trench and said surface of said substrate.

17. A method of forming a buried layer for a high voltage lateral double-diffused metal-oxide-semiconductor transistor on a semiconductor substrate comprising the following steps of:
forming a uniform heavily doped region on a surface of said substrate; and
selectively etching said heavily doped region to form a recess.

18. A method of forming a buried layer for a high voltage lateral double-diffused metal-oxide-semiconductor transistor on a semiconductor substrate comprising the following steps of:
forming a uniform heavily doped region of a first conductivity type on said substrate; and
doping a surface of said heavily doped region with a second conductivity type opposite to said first conductivity type to locally decrease doping concentration of said first conductivity type on said surface of said heavily doped region.
